(19) United States
(12) Patent Application Publication
(10) Pub. No.: US 2008/0003722 A1
(43) Pub. Date: Jan. 3, 2008

(54) Transfer mold solution for molded multi-media card

(76) Inventor: David Dosung Chun, Tempe, AZ (US)

Correspondence Address: STETINA BRUNDA GARRED & BRUCKER, 75 ENTERPRISE, SUITE 250, ALISO VIEJO, CA, 92656, US

(21) Appl. No.: 10/824,999

(22) Filed: Apr. 15, 2004

(51) Int. Cl. H01L 21/00

(52) U.S. Cl. 438/123

(57) ABSTRACT

A method of fabricating a memory card. The method comprises the initial step of providing a leadframe which has a dambar and a plurality of contacts, each of the contacts being attached to the dambar by at least one tie bar. A molded first body section is formed on the leadframe subsequent to the electrical connection of a semiconductor die thereto such that portions of the leadframe other than for the contacts thereof are covered by the first body section. After the tie bars and dambar have been removed from the leadframe, a second body section is formed on the contacts of the leadframe such that portions of the contacts are exposed in a common exterior surface of the second body section. The second body section defines the leading edge of the memory card which has no metal of the leadframe exposed therein.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND OF THE INVENTION

The present invention relates generally to memory cards, and more particularly, to a memory card (e.g., a multi-media card (MMC)) wherein a two-step transfer mold procedure is used to form the memory card body which partially encapsulates the memory card leadframe structure so that the tie bars used to connect the external signal contacts to the outer frame of the leadframe can be removed prior to the complete formation of the body.

As is well known in the electronics industry, memory cards are being used in increasing numbers to provide memory storage and other electronic functions for devices such as digital cameras, MP3 players, cellular phones, and Personal Digital Assistants. In this regard, memory cards are provided in various formats, including multi-media cards and secure digital cards.

Typically, memory cards comprise multiple integrated circuit devices or semiconductor dies. The dies are interconnected using a circuit board substrate which adds to the weight, thickness, stiffness and complexity of the card. Memory cards also include electrical contacts for providing an external interface to an insertion point or socket. These electrical contacts are typically disposed on the backside of the circuit board substrate, with the electrical connection to the dies being provided by vias which extend through the circuit board substrate.

In an effort to simplify the process steps needed to fabricate the memory card, there has been developed by Applicant a memory card wherein a leadframe assembly is used as an alternative to the circuit board substrate, as described in Applicant's co-pending U.S. application Ser. No. 09/956,190 entitled LEAD-FRAME METHOD AND ASSEMBLY FOR INTERCONNECTING CIRCUITS WITHIN A CIRCUIT MODULE filed Sep. 19, 2001, the disclosure of which is incorporated herein by reference. As is described in Ser. No. 09/956,190, the leadframe and semiconductor die of the memory card are covered with an encapsulant which hardens into a cover or body of the memory card. The body is sized and configured to meet or achieve a “form factor” for the memory card. In the completed memory card, the contacts of the leadframe are exposed within a common surface of the body, with the die pad of the leadframe and the semiconductor die mounted thereto being disposed within or covered by the body.

Memory cards, such as multi-media cards, are used by advancing the same into a host socket which includes a plurality of connector pins. Many host sockets include nine connector pins to accommodate the seven contacts included in many memory card formats such as multi-media cards, and the nine contacts included in the secure digital card memory card format. Applicant has previously determined that one of the drawbacks associated with leadframe based memory cards is that portions of the tie bars which are used to connect the contacts to the outer frame of the leadframe are typically exposed in the leading edge of the memory card which is initially advanced into the host socket. More particularly, exposed within this leading edge are the severed ends of the tie bars created as a result of the cutting or singulation process typically used to separate the outer frame of the leadframe from the remainder thereof subsequent to the formation of the body of the memory card. These exposed portions of the tie bars give rise to a potential to short against the metal features of the host socket, and are thus highly undesirable.

The present invention addresses and overcomes the above-described deficiencies of currently known leadframe based memory cards by providing a memory card wherein a two-step transfer mold procedure is used to form the memory card body which partially encapsulates the memory card leadframe structure so that the tie bars used to secure the contacts to the outer frame can be removed prior to the complete formation of the body. More particularly, in an initial step of the fabrication process, a first body section is molded to portions of the leadframe other than for the contacts thereof. This initial molding step is followed by a trimming procedure wherein the outer frame and tie bars used to connect the contacts thereto are removed from the leadframe. Thereafter, a second molding procedure is completed wherein a second body section is molded to the leadframe in a manner partially encapsulating the contacts thereof. Though a portion of each of the contacts is exposed in a common surface of the second body section, no metal is exposed in that surface of the second body section which defines the leading edge of the memory card. These and other attributes of the present invention will be described in more detail below.

### BRIEF SUMMARY OF THE INVENTION

In accordance with the present invention, there is provided a method for manufacturing a memory card such as a multi-media card which involves a two-step molding process. The initial molding step facilitates the formation of a first body section of the memory card which effectively supports the contacts of the leadframe in a manner allowing for the removal of the tie bars of the leadframe used to support the contacts within the outer frame or dambar thereof. Subsequent to the formation of the first body section, a trimming procedure is completed which removes the dambar and the contact supporting tie bars from the remainder of the leadframe. Thereafter, a second, follow-up molding step is completed to facilitate the formation of a second body section of the memory card which partially encapsulates the contacts such that portions of the contacts are exposed in a common surface of the second body section. However, no metal is exposed in that surface of the second body section which defines the leading edge of the memory card.

As a result of the complete removal of the tie bars attaching the contacts of the leadframe to the dambar thereof, the completely formed memory card does not include any tie bar ends exposed in the leading edge thereof. In this regard, the absence of the exposed ends of the tie bars in the leading edge of the memory card eliminates the potential for the tie bars shorting against the metal features of the host socket into which the memory card is to be inserted.

The present invention is best understood by reference to the following detailed description when read in conjunction with the accompanying drawings

### BRIEF DESCRIPTION OF THE DRAWINGS

These, as well as other features of the present invention, will become more apparent upon reference to the drawings wherein:

FIG. 1 is a bottom plan view of a memory card fabricated through the use of the molding method of the present invention;

FIG. 2 is a top plan view of the leadframe of the memory card shown in FIG. 1 prior to the formation of the molded body sections thereon; and

FIGS. 3-5 illustrate an exemplary sequence of steps which may be used to facilitate the fabrication of the memory card in accordance with the present invention

### DETAILED DESCRIPTION OF THE INVENTION

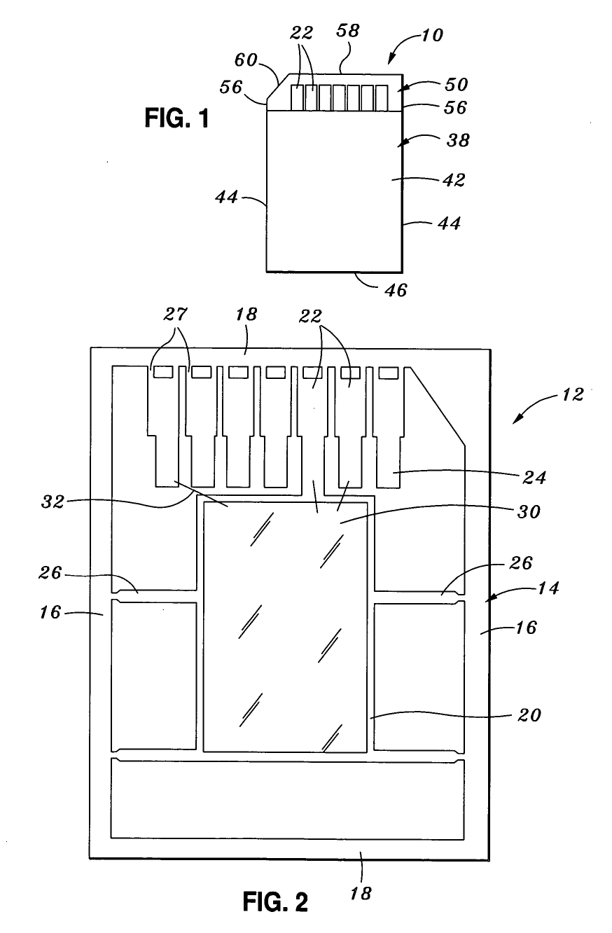

Referring now to the drawings wherein the showings are for purposes of illustrating preferred embodiments of the present invention only, and not for purposes of limiting the same, FIG. 1 depicts a memory card 10 which includes a leadframe 12 best shown in FIG. 2. As shown in FIG. 1, the memory card 10 has a form factor particularly suited for use in a multi-media card memory application. However, those of ordinary skill in the art will recognize that the memory card 10 may have alternative memory card formats, including those of secure digital cards (SDC), compact flash (CF), smart media, memory stick, and other small form factor memory cards.

The leadframe 12 of the memory card 10 comprises an outer frame or dambar 14 which is eventually removed from the leadframe 12 as described below, and thus does not constitute part of the completed memory card 10. Dambar 14 has a generally rectangular configuration defining an opposed pair of longitudinal sides or segments 16 and an opposed pair of lateral sides or segments 18. In addition to the dambar 14, the leadframe 12 includes a die attach area or die pad 20 which is disposed within the interior of the dambar 14. Die pad 20 defines opposed, generally planar top and bottom surfaces. Integrally connected to and extending from one lateral side 18 of the dambar 14 is a plurality of contacts 22 of the leadframe 12. Each of the contacts 22 also defines opposed, generally planar top and bottom surfaces. Integrally connected to and extending from each of the contacts 22 is a conductive trace 24. The traces 24 terminate in close proximity to the die pad 20. Tie bars 26 are used to integrally connect the die pad 20 to the longitudinal sides 16 of the dambar 14. Similarly, one or more tie bars 27 are used to integrally connect the contacts 22 to one lateral side 18 of the dambar 14. In particular, as is seen in FIG. 2, two tie bars 27 are integrally connected to and extend between each contact 22 and the corresponding lateral side 18, though one or more than two tie bars 27 may be used to facilitate such connection.

In the memory card 10, attached to the top surface of the die pad 20 is a semiconductor die 30. The semiconductor die 30 is electrically connected to the leadframe 12, and more particularly to one or more traces 24 alone or in combination with the die pad 20 through the use of conductive wires 32. In this regard, the conductive wires 32 effectively place the semiconductor die 30 into electrical communication with the leadframe 12 and, more particularly, to one or more of the contacts 22 thereof.

The leadframe 12 is preferably fabricated from a conductive metal material (e.g., copper) through either a chemical etching or mechanical stamping process. Those of ordinary skill in the art will recognize that the leadframe 12 may be formed to include any number of contacts 22 depending on the desired application for the memory card 10. As shown in FIG. 1, the memory card 10 includes seven contacts 22 which is the typical number included for a multi-media card application. In the memory card 10, more than one semiconductor die 30 may be attached to the die pad 20. In addition to the semiconductor die(s) 30, the die pad 20 may also accommodate one or more other devices such as passive devices. The semiconductor die(s) 30 alone or in combination with the other devices may, rather than being attached directly to the die pad 20, be attached to an intervening substrate. Further, the leadframe 12 may be configured to define more than one die pad 20, with such multiple die pad(s) each accommodating one or more semiconductor dies alone or in combination with other devices such as passive devices. The pattern of conductive traces 24 may also be varied depending upon the number and arrangement of die pads and the number of semiconductor dies and/or other passive devices included in the memory card 10. Thus, the configuration of the leadframe 12 of the memory card 10 is variable, in that the number and arrangement of semiconductor dies, die pads, contacts, and conductive traces may be varied as needed to satisfy the requirements of a particular application.

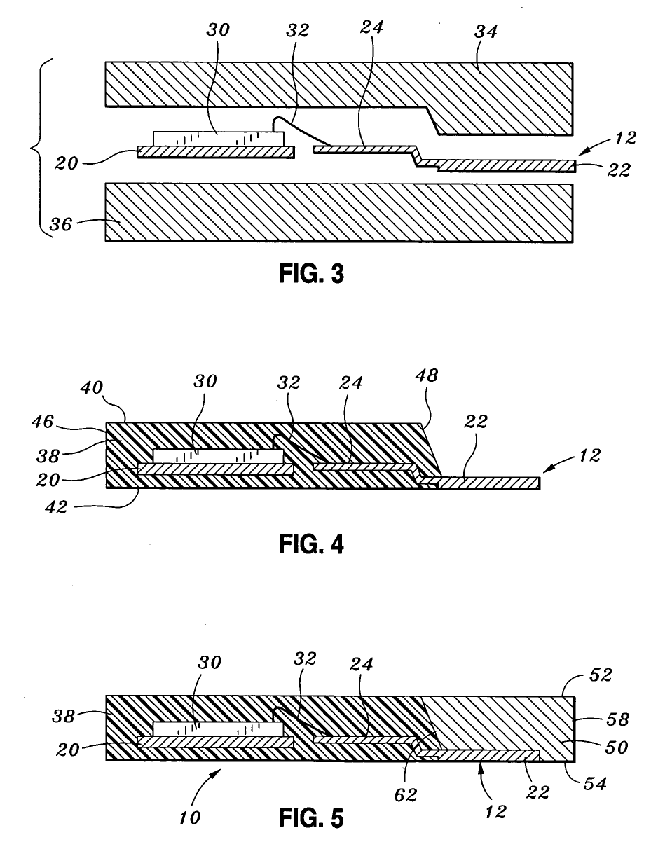

Subsequent to the electrical connection of the semiconductor die 30 to the leadframe 12 in the above-described manner, the leadframe 12 is preferably subjected to a bending operation wherein each of the traces 24 is bent so as to facilitate the creation of an angled or sloped portion therein (as seen in FIGS. 3-5) which is located between the contacts 22 and the die pad 20. The bending of the traces 24 removes the contacts 22 from their original co-planar relationship to the die pad 20. Thus, the contacts 22 and the die pad 20 extend along respective ones of spaced, generally parallel planes. The bending of the leadframe 12 in the above-described manner may occur either prior to the attachment of the semiconductor die 30 to the top surface of the die pad 20, or subsequent to the extension of the conductive wires 32 between the terminals of the semiconductor die 30 and the traces 24.

It is further contemplated that the leadframe 12 will be subjected to a etching process wherein the thicknesses of the traces 24 are reduced in comparison to the remainder of the leadframe 12. As shown in FIGS. 3-5, the traces 24 are subjected to a half-etching process such that the thicknesses thereof is approximately half that of the contacts 22 and die pad 20 of the leadframe 12. Thus, those portions of the traces 24 which are integrally connected to the contacts 22 and are not up-set as a result of the completion of the aforementioned bending operation are still perpendicularly recessed inwardly relative to the bottom surfaces of the contacts 22.

Referring now to FIGS. 3-5, in accordance with the present invention, the memory card 10 is fabricated by initially forming the leadframe 12 to have the above-described structural attributes. Thereafter, the semiconductor die(s) 30 and/or other devices are secured to the top surface of the die pad 20 and electrically connected thereto and/or to the traces 24 through the use of the conductive wires 32. Thereafter, the leadframe 12 is optionally bent in the above-described manner to facilitate the formation of the angled or sloped portion within each of the traces 24.

The leadframe 12 next is placed into a mold cavity collectively defined by a top mold section 34 and a bottom mold section 36 (FIG. 3). The leadframe 12 is preferably captured between the top and bottom mold sections 34, 36 such that the top surfaces of the contacts 22 are completely or substantially covered by a portion of the top mold section 34, with the bottom surfaces of the contacts 22 being completely covered by a portion of the bottom mold section 36. Thus, with the contacts 22 of the leadframe being captured between the top and bottom mold sections 34, 36, the traces 24 and die pad 30 of the leadframe reside in an open area of the mold cavity in spaced relation to the top and bottom mold sections 34, 36, as do the semiconductor die 30 and conductive wires 32 interfaced to the leadframe 12.

Subsequent to the placement of the leadframe 12 between the top and bottom mold sections 34, 36 in the above-described manner, a first molding step is conducted wherein an encapsulant material is injected into the open area of the mold cavity defined between the top and bottom mold sections 34, 36. The encapsulant material flows about and completely encapsulates the die pad 20 and traces 24 of the leadframe 12, as well as the semiconductor die 30 and conductive wires 32. The encapsulant material is preferably a plastic (e.g., thermoset, thermoplastic) which, upon hardening, forms a molded first body section 38 of the memory card 10 (FIG. 4). The first body section 38 defines a generally planar top surface 40, an opposed, generally planar bottom surface 42, an opposed pair of longitudinal side surfaces 44, and a lateral side surface 46. The first body section 38 further defines a sloped lateral side surface 48. While the longitudinal side surfaces 44 and lateral side surface 46 extend generally perpendicularly between the top and bottom surfaces 40, 42, the sloped lateral side surface 48 extends non-perpendicularly between the top and bottom surfaces 40, 42 and is disposed adjacent to the contacts 22 of the leadframe 12. Thus, as is further seen in FIG. 4, the contacts 22 protrude from the sloped lateral side surface 48 of the first body section 38. It is contemplated that the die pad 20 of the leadframe 12 may be formed to be of sufficient thickness such that the bottom surface thereof is exposed in and substantially flush with the bottom surface 42 of the first body section 38.

The bending of the leadframe 12 and resultant formation of the angled portions within the traces 24 in the aforementioned manner allows the up-set die pad 20 and up-set portions of the traces 24 (as well as the semiconductor die 30 and conductive wires 32 interfaced thereto) to be completely encovered or encapsulated by the encapsulant material, and hence the first body section 38. Even those portions of the traces 24 which are not up-set are completely covered or encapsulated by the first body section 38 due to the same being of reduced thickness in comparison to the contacts 22 as a result of the completion of the above-described partial etching process. Thus, no portion of any of the traces 24 is exposed in the first body section 38 of the memory card 10.

Subsequent to the formation of the first body section 38, the leadframe 12 is subjected to a singulation process wherein the dambar 14 is removed from the remainder of the leadframe 12. Such removal typically entails cutting portions of the tie bars 26 which protrude from the first body section 38, in addition to trimming or removing the tie bars 27 from the contacts 22. It is contemplated that the singulation process may be completed through a sawing or punching operation. The complete formation of the first body section 38 allows for the removal of the tie bars 27 since the contacts 22 are supported and maintained in prescribed orientations relative to each other as a result of the traces 24 integrally connected thereto being embedded within the first body section 38.

Subsequent to the formation of the first body section 38 and removal of the dambar 14 in the above-described manner, the partially fabricated memory card 10 is placed into another suitably shaped mold cavity which, upon the injection of additional encapsulant material thereinto, facilitates the formation of a molded second body section 50 of the memory card 10 (FIG. 5). The second body section 50 itself defines a generally planar top surface 52, an opposed, generally planar bottom surface 54, an opposed pair of lateral side surfaces 56, and a longitudinal side surface 58. Extending angularly between the longitudinal side surface 58 and one of the lateral side surfaces 56 is a sloped side surface 60. The second body section 50 further defines a sloped longitudinal side surface 62 which is complimentary to and abutted against the sloped lateral side surface 48 of the first body section 38. In addition to the side surfaces 48, 62 being engaged to each other, the top surface 52 of the second body section 50 extends in generally co-planar, continuous relation to the top surface 40 of the first body section 38. Similarly, the bottom surface 54 of the second body section 58 extends in generally co-planar, continuous relation to the bottom surface 42 of the first body section 38, with the lateral side surfaces 56 of the first body section 58 extending in generally co-planar, continuous relation to respective ones of the longitudinal side surfaces 44 of the first body section 38. The bottom surfaces of the contacts 22 of the leadframe 12 are exposed in and substantially flush with the bottom surface 54 of the second body section 50.

The formation of the second body section 50 completes the fabrication of the memory card 10. This fabrication technique wherein the tie bars 27 are completely removed prior to the formation of the second body section 50 allows the distal ends of the contacts 22 (i.e., those ends opposite the ends having the traces 24 protruding therefrom) to be completely covered by the second body section 50. As a result, no severed distal ends of the tie bars 27 remain exposed in the longitudinal side 58 of the second body section 50 which itself defines the leading edge of the memory card 10. The absence of any exposed metal in the leading edge of the memory card 10 eliminates potential occurances of shorting against the metal features of the host socket. As indicated above, this represents a departure from and provides a significant advantage over currently known fabrication techniques wherein the severed distal ends of the tie bars used to support the contacts of the leadframe within the dambar thereof remain exposed in the leading edge of the memory card subsequent to the complete fabrication thereof.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure

1. A method of fabricating a memory card, comprising the steps of:
a) providing a leadframe having
a plurality of contacts defining opposed top and bottom contact surfaces;
b) electrically connecting at least one semiconductor die to the leadframe;
c) forming a first body section on the leadframe which at least partially encapsulates the semiconductor die and a first portion of the leadframe; and
d) forming a second body section on the leadframe which at least partially encapsulates a second portion of the leadframe, the first and second body sections being formed such that at least portions of the bottom contact surfaces of the contacts are exposed in an exterior surface of a memory card body collectively defined by the first and second body sections.

2. The method of claim 1 wherein:
step (a) comprises providing a leadframe having a die pad which defines opposed top and bottom die pad surfaces;
step (b) comprises attaching the semiconductor die to the top die pad surface of the die pad; and
step (c) comprises forming the first body section to at least partially encapsulate the die pad.

3. The method of claim 2 wherein:
step (a) comprises providing a leadframe having a plurality of conductive traces which extend from respective ones of the contacts toward the die pad;
step (b) comprises electrically connecting the semiconductor die to at least one of the conductive traces; and
step (c) comprises forming the first body section such that the conductive traces are at least partially encapsulated thereby.

4. The method of claim 3 wherein step (a) comprises providing a leadframe which is partially etched such that each of the conductive traces has a trace thickness which is less than a contact thickness of each of the contacts and a die pad thickness of the die pad.

5. The method of claim 3 wherein step (a) comprises providing a leadframe wherein the conductive traces are bent such that the die pad and the contacts extend along respective ones of spaced, generally parallel planes.

6. The method of claim 3 wherein step (c) comprises forming the first body section such that the die pad, the semiconductor die and the traces are at least partially encapsulated thereby, and at least portions of the contacts protrude from a common side surface thereof.

7. The method of claim 1 wherein:
step (a) comprises providing a leadframe wherein the bottom contact surfaces of the contacts are each generally planar; and
steps (c) and (d) comprise forming the first and second body sections such that the exterior surface of the memory card body is generally planar and the bottom contact surfaces of the contacts are exposed in and substantially flush with the exterior surface.

8. The method of claim 1 wherein step (d) comprises forming the second body section to abut the first body section.

9. The method of claim 8 wherein:
step (c) comprises forming the first body section to define a first sloped side surface; and
step (d) comprises forming the second body section to define a second sloped side surface which is abutted against the first sloped side surface and has an angle complimentary thereto.

10. The method of claim 1 wherein:
step (a) comprises providing a leadframe which includes a dambar and wherein each of the contacts is attached to the dambar by at least one tie bar; and
step (c) comprises removing the dambar and the tie bars from the leadframe subsequent to forming the first body section.

11. A method of fabricating a memory card, comprising the steps of:
a) providing a leadframe having a plurality of contacts defining opposed top and bottom contact surfaces;
b) electrically connecting at least one semiconductor die to the leadframe;
c) forming a first body section on the leadframe which encapsulates the semiconductor die and a portion of the leadframe other than for the contacts thereof; and
d) forming a second body section on the leadframe which partially encapsulates the contacts such that at least portions of the bottom contact surfaces of the contacts are exposed in an exterior surface of the second body section.

12. The method of claim 11 wherein:
step (a) comprises providing a leadframe having a die pad;
step (b) comprises attaching the semiconductor die to the die pad; and
step (c) comprises forming the first body section to at least partially encapsulate the die pad.

13. The method of claim 12 wherein:
step (a) comprises providing a leadframe having a plurality of conductive traces which extend from respective ones of the contacts toward the die pad;
step (b) comprises electrically connecting the semiconductor die to at least one of the conductive traces; and
step (c) comprises forming the first body section such that the conductive traces are encapsulated thereby.

14. The method of claim 13 wherein step (a) comprises providing a leadframe which is partially etched such that each of the conductive traces has a trace thickness which is less than a contact thickness of each of the contacts and a die pad thickness of the die pad.

15. The method of claim 13 wherein step (a) comprises providing a leadframe wherein the conductive traces are bent such that the die pad and the contacts extend along respective ones of spaced, generally parallel planes.

16. The method of claim 13 wherein step (c) comprises forming the first body section such that the die pad, the semiconductor die and the traces are encapsulated thereby, and the contacts protrude from a common side surface thereof.

17. The method of claim 11 wherein:
step (a) comprises providing a leadframe wherein the bottom contact surfaces of the contacts are each generally planar; and
step (d) comprises forming the second body section such that the exterior surface thereof is generally planar and the bottom contact surfaces of the contacts are exposed in and substantially flush with the exterior surface.

18. The method of claim 11 wherein step (d) comprises forming the second body section to abut the first body section.

19. The method of claim 18 wherein:
step (c) comprises forming the first body section to define a first sloped side surface; and
step (d) comprises forming the second body section to define a second sloped side surface which is abutted against the first sloped side surface and has an angle complimentary thereto.

20. The method of claim 11 wherein steps (c) and (d) comprise forming the first and second body sections from a common plastic material.
